(19) United States
(12) Patent Application Publication
(10) Pub. No.: US 2002/0189763 A1
(43) Pub. Date: Dec. 19, 2002

(54) Plasma processing apparatus having parallel resonance antenna for very high frequency

(75) Inventors: Gi Chung Kwon, Kwangju-gun (KR); Hong Sik Byun, Songnam-shi (KR); Sung Weon Lee, Yongin-shi (KR); Hong Seub Kim, Yongin-shi (KR); Sun Seok Han, Suwon-shi (KR); Bu Jin Ko, Taejon (KR); Joung Sik Kim, Seochun-gun (KR)

Correspondence Address: MARGER JOHNSON & MCCOLLOM PC, 1030 SW MORRISON STREET, PORTLAND, OR, 97205, US

(73) Assignee: Jusung Engineering Co., Ltd., Kawagju-gun (KR)

(21) Appl. No.: 10/174,900

(22) Filed: Jun. 17, 2002

(30) Foreign Application Priority Data
Jun. 19, 2001 (KR) 2001-34612

(51) Int. Cl. C23F 1/00; C23C 16/00

(52) U.S. Cl. 156/345.48; 118/723 AN

(57) ABSTRACT

Disclosed is a plasma process apparatus in which a semiconductor device manufacturing process using a plasma is performed. The apparatus includes: a vacuum chamber in which a semiconductor device manufacturing process is performed; a very high frequency (VHF) power source for generating a VHF power; a VHF parallel resonance antenna having a plurality of antenna coils connected in parallel to each other, and multiple variable capacitors insertion-installed in series in the antenna coils, the antenna being installed at an outer upper portion of the vacuum chamber, and supplied with the VHF power from the VHF power source; and an impedance matching box for impedance matching between the VHF power and the VHF parallel resonance antenna. Preferably, the variable capacitor is a coaxial capacitor including: a first insulator tube; first two metal tubes respectively extending from both ends of the first insulator tube; a second insulator tube surrounding the first insulator tube, and partially surrounding the first two metal tubes placed adjacent to both sides thereof; and a second metal tube surrounding the second insulator tube, and installed so as to glide along an outer side surface of the second insulator tube.

### BACKGROUND OF THE INVENTION

1. Field of the Invention

The present invention relates to a plasma process apparatus, and more particularly, to an inductively coupled plasma process apparatus provided with a parallel resonance antenna for very high frequency.

2. Description of the Related Art

In semiconductor device manufacturing processes, processes using plasma are frequently performed. Dry etching, chemical vapor deposition (CVD) and sputtering are examples of such processes. In order to reconsider the process efficiency, a process using a high density plasma (HDP) having an ion concentration of approximately 1×10¹¹-2×10¹² ions/cm³ is frequently employed at the present. It is well known that this high density plasma can be obtained by inductively coupled plasma (ICP).

FIG. 1a is a schematic view for illustrating a conventional inductively coupled plasma process apparatus.

Referring to FIG. 1a, a wafer chuck 20 is provided in a vacuum chamber 10. A wafer 30 is mounted on the wafer chuck 20. The vacuum chamber 10 is provided with a gas injection hole 12 and a gas exhaust hole 14. By injecting gas through the gas injection hole 12 at a constant flow rate and exhausting gas through the gas exhaust hole 14, the vacuum chamber 10 is maintained at a constant pressure state.

The vacuum chamber 10 includes an insulator plate 50 arranged at the upper portion thereof. On the insulator plate 50 is disposed a parallel resonance antenna 60. If a radio frequency (RF) power is supplied to the parallel resonance antenna 60 through an RF power source 75, since the parallel resonance antenna 60 has the structure shown in FIG. 1b, magnetic field is induced in the parallel resonance antenna, and thus an induced electric field is again generated. The induced electric field activates gases within the vacuum chamber 10, so that plasma 40 is generated. Between the parallel resonance antenna 60 and the vacuum chamber 10 is formed a stray capacitor, Cs.

For the impedance matching between the RF power source 75 and the parallel resonance antenna 60, an impedance matching box (IMB) 70 is installed. Although not shown in the drawings, in order to generate plasma, a separate RF power is connected even with the wafer chuck 20 and then an RF power may be applied thereto.

FIG. 1b is a schematic view showing an arrangement relationship between the parallel resonance antenna 60 and the impedance matching box 70 shown in FIG. 1a, and FIGS. 1c and 1d are equivalent circuit diagrams in which the stray capacitor, Cs is included in FIG. 1b.

Referring to FIG. 1b to FIG. 1d, the parallel resonance antenna 60 includes antenna coils L1, L2, L3 and L4 connected in parallel with each other. Here, the respective antenna coils have different diameters from each other in ring shapes. The antenna coil L4 is arranged outermost.

Between the impedance matching box 70 and the outermost antenna coil L4, there is installed a resonance capacitor C3 not shown in FIG. 1a. In FIG. 1b, symbol La represents an overall inductance of the parallel resonance antenna 60.

If contributions of the inner antenna coils L1, L2 and L3 are intentionally neglected, the stray capacitor, Cs is in a state to be connected in parallel with the outermost antenna coil L4. As the frequency of the RF power applied from the RF power source 75 increases, capacitive energy in the energy transferred to plasma becomes superior to inductive energy. In other words, as the frequency of the plasma power increases, contribution of the stray capacitor, Cs becomes larger, so that the plasma 40 is formed by a capacitively coupled type. Accordingly, influence of the capacitively coupled plasma (CCP) to the inductively coupled plasma (ICP) becomes so large to non-negligible degree, that uniformity of the plasma is deteriorated.

Meanwhile, resonance frequency, ω between the resonance capacitor C3 and the parallel resonance antenna 60 can be represented by an equation of 1/(La·C3)^{1/2}. Then, since La is fixed by a geometrical structure of the parallel resonance antenna 60, resonance in the RF region of 20 MHz to 300 MHz can occur only by using a very small value of C3. However, the conventional variable capacitor used as the resonance capacitor C3 is manufactured in products having a capacitance of 5 pF or more, resonance in the RF region of 20 MHz to 300 MHz is not generated as desired in fact.

Thus, if the resonance is not generated as desired, the contribution of the stray capacitor Cs becomes large, so that the plasma 40 is mainly formed by the capacitively coupled type.

### SUMMARY OF THE INVENTION

Accordingly, it is a technical object of the invention to provide a plasma process apparatus capable of obtaining a uniform high density plasma by allowing resonance to be generated in the parallel resonance antenna in the very high frequency (VHF) region of 20 MHz-300 MHz and thus influence of the stray capacitor placed between the parallel resonance antenna and the vacuum chamber to be minimized.

To accomplish the above object, there is provided a plasma process apparatus in which a semiconductor device manufacturing process using plasma is performed. The apparatus includes: a vacuum chamber in which a semiconductor device manufacturing process is performed; a very high frequency (VHF) power source for generating a VHF power; a VHF parallel resonance antenna having a plurality of antenna coils connected in parallel to each other, and multiple variable capacitors insertion-installed in series in the antenna coils, the antenna being installed at an outer upper portion of the vacuum chamber, and supplied with the VHF power from the VHF power source; and an impedance matching box for impedance matching between the VHF power and the VHF parallel resonance antenna.

The variable capacitor is preferably installed in the antenna coil positioned outermost in the VHF parallel resonance antenna. Preferably, the variable capacitor has a capacitance ranged from 1 pF to 5 pF.

Selectively, the VHF parallel resonance antenna is a spiral type parallel antenna, and it is desirous that the variable capacitors are respectively installed in the antenna coils. The VHF parallel resonance antenna comprises ring-shaped coil antennas connected in parallel with each other and having different diameters.

Preferably, the variable capacitor is a coaxial capacitor includes: a first insulator tube; first two metal tubes respectively extending from both ends of the first insulator tube; a second insulator tube surrounding the first insulator tube, and partially surrounding the first two metal tubes placed adjacent to both sides thereof; and a second metal tube surrounding the second insulator tube, and installed so as to glide along an outer side surface of the second insulator tube.

### BRIEF DESCRIPTION OF THE DRAWINGS

The above object and other advantages of the present invention will become more apparent by describing in detail preferred embodiments thereof with reference to the accompanying drawings in which:

FIGS. 1a to 1d are schematic views for illustrating a conventional inductively coupled plasma process apparatus;

FIGS. 2a to 2c are schematic views for illustrating a parallel resonance antenna for very high frequency in accordance with the present invention;

FIG. 3 is a schematic view for illustrating a coaxial capacitor serving as a variable capacitor in accordance with the present invention; and

FIGS. 4a to 4c are schematic views showing examples of various applications in accordance with the present invention.

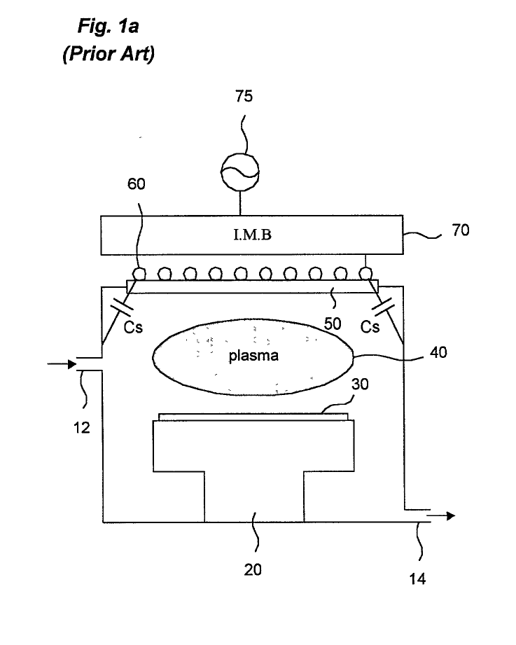

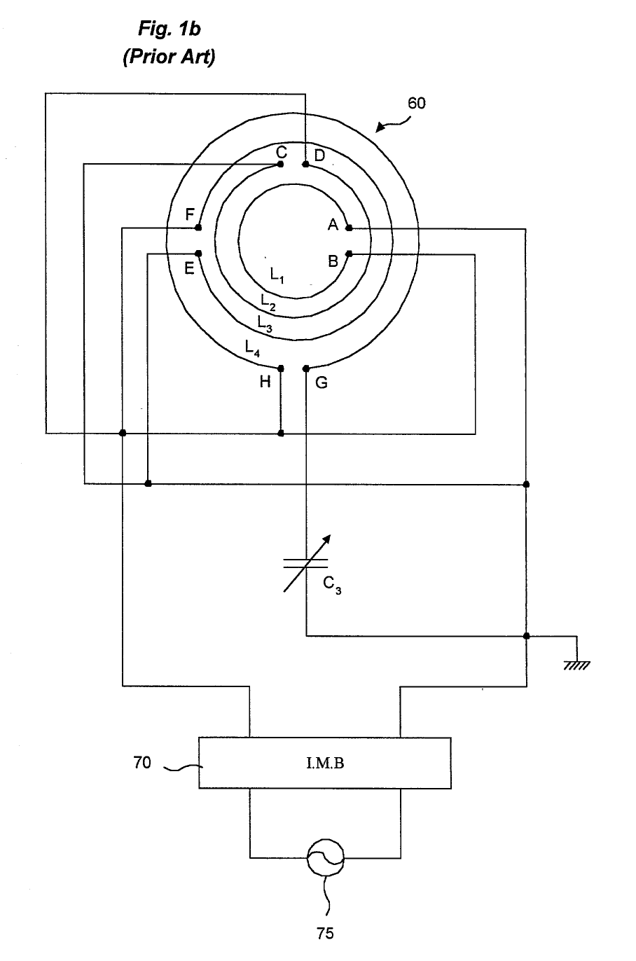

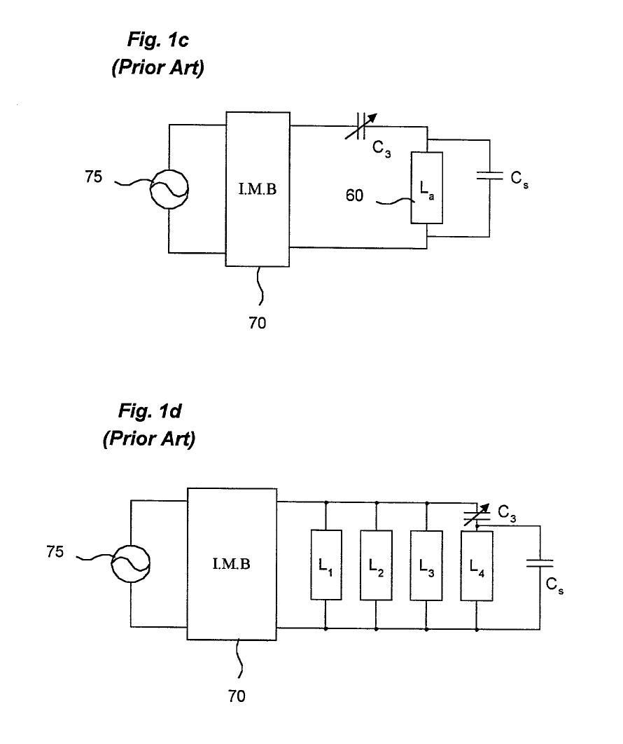

### DETAILED DESCRIPTION OF THE PREFERRED EMBODIMENT

Now, preferred embodiments of the present invention will be described in detail with reference to the accompanying drawings. In reference numeral assigned to elements of respective drawings, it is noted that identical reference numerals with those assigned to the elements of the conventional art represent elements performing the same functions and their repeated descriptions are intentionally omitted.

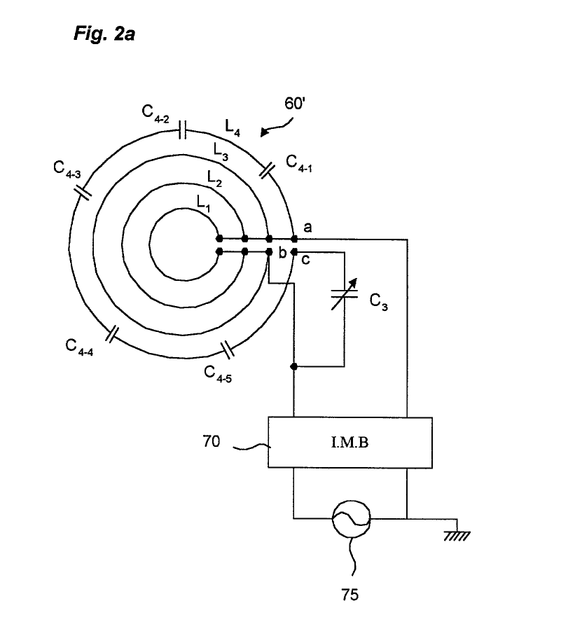

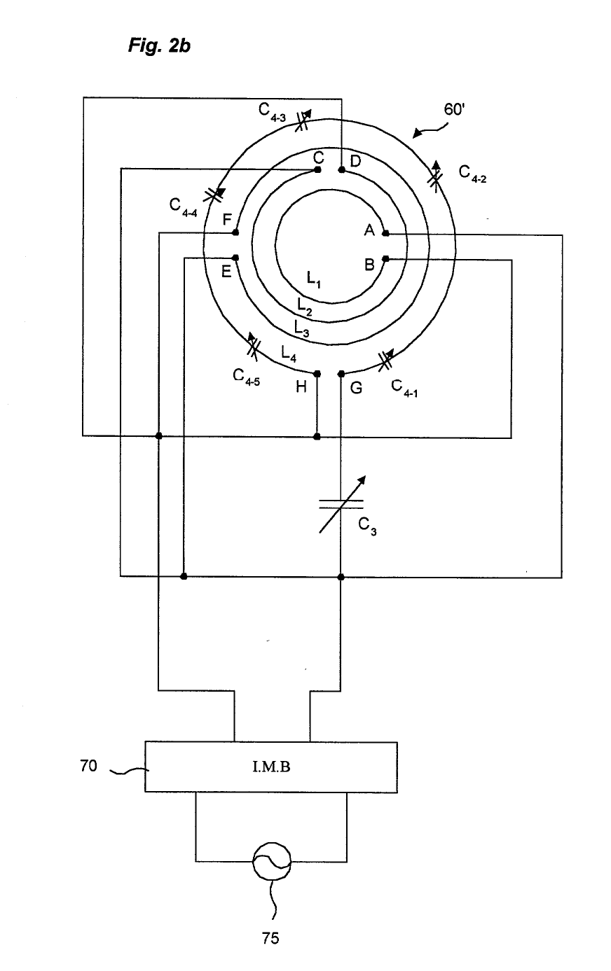

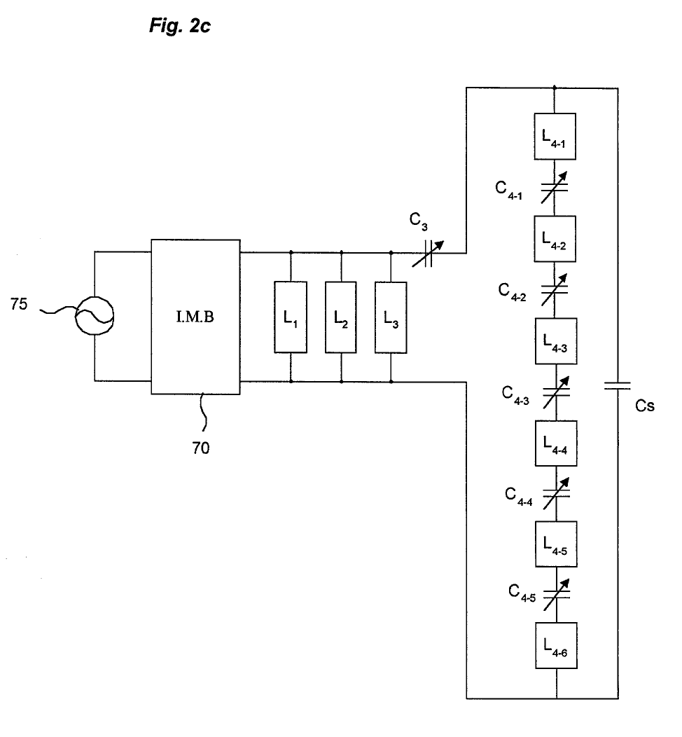

FIGS. 2a to 2c are schematic views for illustrating a parallel resonance antenna for very high frequency in accordance with the present invention. Specifically, FIGS. 2a and 2b are schematic views showing an arrangement relationship between a very high frequency (VHF) parallel resonance antenna 60′ and an impedance matching box 70, and FIG. 2c shows an equivalent circuit diagram in which a stray capacitor is included in FIGS. 2a and 2b.

Referring to FIGS. 2a to 2c, the VHF parallel resonance antenna 60′ includes antenna coils L1, L2, L3, and L4 connected in parallel with each other. The respective antenna coils have different diameters in ring shapes. The antenna coil L4 is positioned outermost.

A VHF power having a frequency ranged from 20 MHz to 300 MHz is supplied through an RF (Radio Frequency) power 75. The VHF power transferred to the inner antenna coils L1, L2, and L3 contributes to the generation of an inductive plasma, while the VHF power transferred to the antenna coil L4 contributes to the generation of a capacitive plasma.

In order to decrease influence of the stray capacitor Cs, it is needed to minimize the capacitance of a resonance capacitor C3 and thus generate resonance between the resonance capacitor C3 and the VHF parallel resonance antenna 60′.

However, the conventional vacuum variable capacitor used as the resonance capacitor C3 does not include a product having a capacitance of 5 pF or less. To this end, in order to lower the capacitance of the resonance capacitor C3, several variable capacitors should be connected in series, thereby simply decreasing the overall capacitance. At this time, use of a new variable capacitor having the capacitance of 5 pF or less maximizes such effects.

Multiple variable capacitors are insertion-installed in series at the outermost antenna coil L4. If the overall capacitance decreases sufficiently only by the variable capacitor newly inserted, there is no needed the conventional resonance capacitor C3.

Since the stray capacitor is influenced less by the inner antenna coils L1, L2, and L3 than by the outermost antenna coil L4, the multiple variable capacitors are installed only at the outermost antenna coil L4.

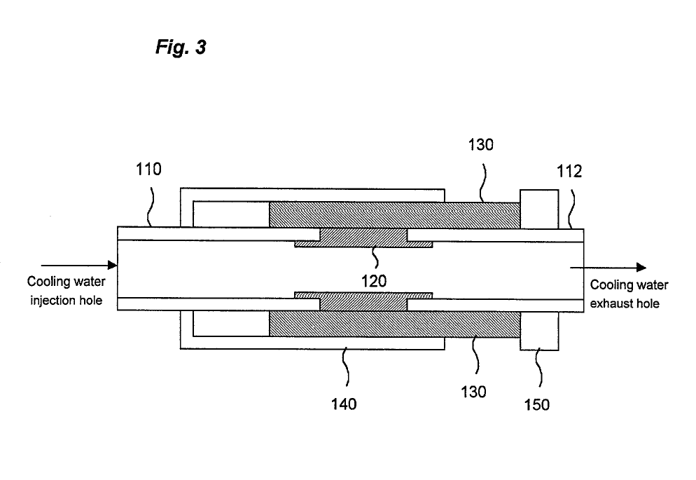

FIG. 3 is a schematic view for illustrating a coaxial capacitor serving as a variable capacitor in accordance with the present invention.

Referring to FIG. 3, first two metal tubes 110 and 112 are connected through a first insulator tube 120 with each other. At the connected portion is installed a second insulator tube 130 surrounding the first insulator tube 120. The second insulator tube 130 surrounds the first insulator tube and also partially surrounds the first two metal tubes 110 and 112 placed adjacent to both sides thereof.

A second metal tube 140 surrounds the second insulator tube, and it is installed so as to glide along an outer side surface of the second insulator tube. At one end of the second insulator tube 130 is installed a stop plate 150 for preventing the second metal tube 140 from gliding. The outermost coil antenna L4 is wound on the respective first two metal tubes 110 and 112, so that the coaxial capacitor is shaped to be insertion-installed at the outermost coil antenna L4.

This coaxial capacitor has advantages in which a capacitance ranged from 1 pF to 5 pF can be secured, and the capacitance value can be finely controlled. Also, by flowing a cooling water through the first two metal tubes 110 and 112, and the first insulator tube 120, there occurs an advantage in which heat generated by the VHF power can be radiated to the outside.

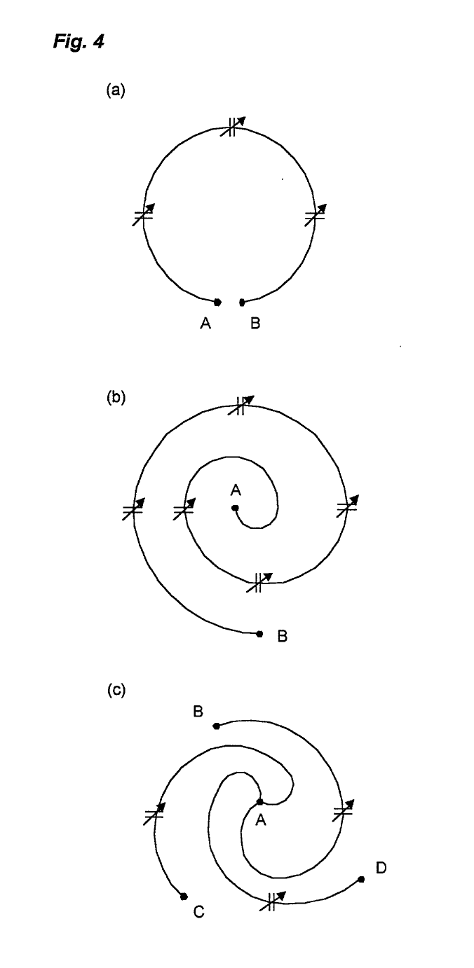

FIGS. 4a to 4c are schematic views showing examples of various applications in accordance with the present invention. Specifically, FIG. 4a shows that multiple coaxial capacitors are installed in the antenna coil wound once, FIG. 4b shows that multiple coaxial capacitors are installed in a spiral type serial antenna wound by the antenna coil several times, and FIG. 4c shows that multiple coaxial capacitors are installed in a spiral type parallel antenna in which multiple antenna coils are connected in parallel with each other.

In the case of FIG. 4c, since the respective antenna coils substantially function as the outermost antenna coil, it is preferable to install the coaxial capacitors with respect to the respective antenna coils. Since the parallel type antenna has an overall inductance value less than that of the serial type antenna, the parallel type antenna is more advantageous for the VHF plasma apparatus. Accordingly, the case of FIG. 4c is better than the cases of FIGS. 4a and 4b for the VHF apparatus.

As described previously, according to a plasma process apparatus of the present invention, resonance is so generated in the parallel resonance antenna even in the VHF region, that influence of the stray capacitor placed between the parallel resonance antenna and the vacuum chamber upon the plasma process apparatus is minimized. Thus, by using the plasma process apparatus in accordance with the present invention, it becomes possible to form a uniform high density plasma.

Although the preferred embodiments of the present invention have been disclosed for illustrative purposes, those skilled in the art will appreciate that various modifications, additions and substitutions can be made without departing from the scope and spirit of the invention as disclosed in the accompanying claims.

What is claimed is:

1. A plasma process apparatus in which a semiconductor device manufacturing process using a plasma is performed, the apparatus comprising:
a vacuum chamber in which a semiconductor device manufacturing process is performed;
a very high frequency (VHF) power source for generating a VHF power;
a VHF parallel resonance antenna having a plurality of antenna coils connected in parallel to each other, and multiple variable capacitors insertion-installed in series in the antenna coils, the antenna being installed at an outer upper portion of the vacuum chamber, and supplied with the VHF power from the VHF power source; and
an impedance matching box for impedance matching between the VHF power and the VHF parallel resonance antenna.

2. The plasma process apparatus as claimed in claim 1, wherein the variable capacitor is installed at the antenna coil positioned outermost.

3. The plasma process apparatus as claimed in claim 1, wherein the VHF parallel resonance antenna is a spiral type parallel antenna, and the variable capacitors are respectively installed in the antenna coils.

4. The plasma process apparatus as claimed in claim 1, wherein the VHF parallel resonance antenna comprises ring-shaped coil antennas connected in parallel with each other and having different diameters.

5. The plasma process apparatus as claimed in claim 1, wherein the VHF power has a frequency ranged from 20 MHz to 300 MHz.

6. The plasma process apparatus as claimed in claim 1, wherein the variable capacitor is a coaxial capacitor comprising:
a first insulator tube;
first two metal tubes respectively extending from both ends of the first insulator tube;
a second insulator tube surrounding the first insulator tube, and partially surrounding the first two metal tubes placed adjacent to both sides thereof; and
a second metal tube surrounding the second insulator tube, and installed so as to glide along an outer side surface of the second insulator tube.

7. The plasma process apparatus as claimed in claim 6, wherein a coolant flows through the first two metal tubes and the first insulator tube.

8. The plasma process apparatus as claimed in claim 1, wherein the variable capacitor has a capacitance ranged from 1 pF to 5 pF.
